(19) United States
(12) Patent Application Publication
(10) Pub. No.: US 2023/0099398 A1
(43) Pub. Date: Mar. 30, 2023

(54) SUBSTRATE SUPPORT, SUBSTRATE PROCESSING APPARATUS, AND ELECTROSTATIC ATTRACTION METHOD

(71) Applicant: Tokyo Electron Limited, Tokyo (JP)

(72) Inventor: Shinsuke OKA, Miyagi (JP)

(73) Assignee: Tokyo Electron Limited, Tokyo (JP)

(21) Appl. No.: 17/949,004

(22) Filed: Sep. 20, 2022

(30) Foreign Application Priority Data
Sep. 28, 2021 (JP) 2021-157768

(51) Int. Cl. H01J 37/32

(52) U.S. Cl. CPC H01J 37/32642; H01J 37/32724; H01L 21/6833

(57) ABSTRACT

There is a substrate support comprising: a base; an electrostatic chuck disposed on the base and having a substrate supporting surface to support the substrate; and an edge ring disposed to surround the substrate on the substrate supporting surface, wherein the electrostatic chuck has a ring supporting surface to support the edge ring, and an inner edge side of the ring supporting surface is lower than an outer edge side of the ring supporting surface.

### CROSS-REFERENCE TO RELATED APPLICATIONS

This application claims priority to Japanese Patent Application No. 2021-157768 filed on Sep. 28, 2021, the entire contents of which are incorporated herein by reference.

### TECHNICAL FIELD

The present disclosure relates to a substrate support, a substrate processing apparatus, and an electrostatic attraction method.

### BACKGROUND

Japanese Laid-open Patent Publication No. 2016-122740 discloses a substrate processing apparatus. The substrate processing apparatus includes a supply for supplying a thermal medium to a space between an electrostatic chuck on which a substrate is mounted and a focus ring which surrounds an area in which the substrate is mounted. In addition, the substrate processing apparatus includes a plurality of electrodes which are provided in a region corresponding to the focus ring in the electrostatic chuck and to which a voltage for attracting the focus ring to the electrostatic chuck is applied.

### SUMMARY

The technique according to the present disclosure restrains a leakage of heat transfer gas.

In accordance with an aspect of the present disclosure, there is a substrate support comprising: a base; an electrostatic chuck disposed on the base and having a substrate supporting surface to support the substrate; and an edge ring disposed to surround the substrate on the substrate supporting surface, wherein the electrostatic chuck has a ring supporting surface to support the edge ring, and an inner edge side of the ring supporting surface is lower than an outer edge side of the ring supporting surface.

### BRIEF DESCRIPTION OF THE DRAWINGS

The objects and features of the present disclosure will become apparent from the following description of embodiments, given in conjunction with the accompanying drawings, in which:

FIG. 1 is a diagram showing a state of a conventional substrate support when an inside of a chamber is at atmospheric pressure.

FIG. 2 is a diagram showing a state of the conventional substrate support when the inside of the chamber is evacuated.

FIG. 3 is an explanatory diagram schematically showing the configuration of a plasma processing system.

FIG. 4 is a longitudinal sectional view schematically showing the configuration of a plasma processing apparatus.

FIG. 5 is a cross-sectional view illustrating a state of a substrate support in a plasma processing chamber, showing a state when the entire periphery of the substrate support is at atmospheric pressure.

FIG. 6 is a partially enlarged cross-sectional view of FIG. 5.

FIG. 7 is a diagram showing a main part of the substrate support when the plasma processing chamber is decompressed.

FIG. 8 is a flowchart illustrating an example of a method for electrostatic attraction of an edge ring.

FIG. 9 is a diagram showing the state of the electrostatic chuck during the process of mounting the edge ring.

FIG. 10 is a diagram showing another example of a ring supporting surface.

FIG. 11 is a diagram which shows another example of a ring supporting surface.

FIG. 12 is a diagram showing another example of a ring supporting surface.

FIG. 13 is a diagram showing another example of a ring supporting surface and an edge ring.

FIG. 14 is a diagram for explaining an example of a form of applying a voltage to an electrode for electrostatic attraction of an edge ring.

FIG. 15 is a diagram for explaining an example of a form of applying a voltage to an electrode for electrostatic attraction of an edge ring.

FIG. 16 is a cross-sectional view showing another example of the edge ring.

FIG. 17 is a diagram illustrating an example of a substrate support further having a cover ring.

FIG. 18 is a diagram showing another example of a substrate supporting surface.

### DETAILED DESCRIPTION

In a semiconductor device manufacturing process, plasma processing is performed on a substrate such as a semiconductor wafer (hereinafter, referred to as “wafer”). In plasma processing, plasma is generated by exciting a processing gas, and the substrate is processed by the plasma.

Plasma processing is performed by a substrate processing apparatus. The substrate processing apparatus generally includes a substrate support and a chamber. The substrate support includes a base and an electrostatic chuck disposed on the base and having a substrate supporting surface for supporting a substrate. The chamber is configured to be decompressed/depressurized and accommodates the substrate support. In addition, in order to improve uniformity of the plasma processing of the substrate, an edge ring is disposed on the electrostatic chuck in order to surround the substrate supported by the substrate supporting surface. The edge ring is supported and electrostatically attracted by a ring supporting surface of the electrostatic chuck which is formed to surround the substrate supporting surface.

In addition, the substrate support is configured such that a flow path through which a fluid for temperature control flows is formed therein and a heat transfer gas such as helium (He) gas is supplied between the ring supporting surface of the electrostatic chuck and the edge ring. Due to the above-described configuration, it is possible to control the temperature of the edge ring even if the temperature of the edge ring rises due to a heat input from the plasma during the plasma processing.

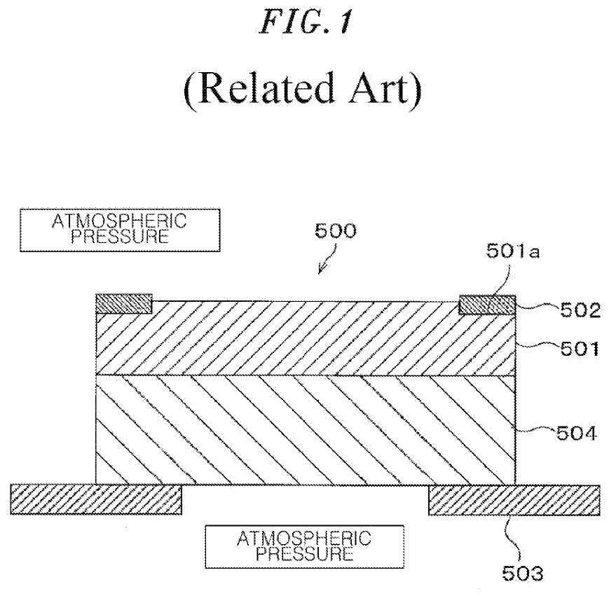

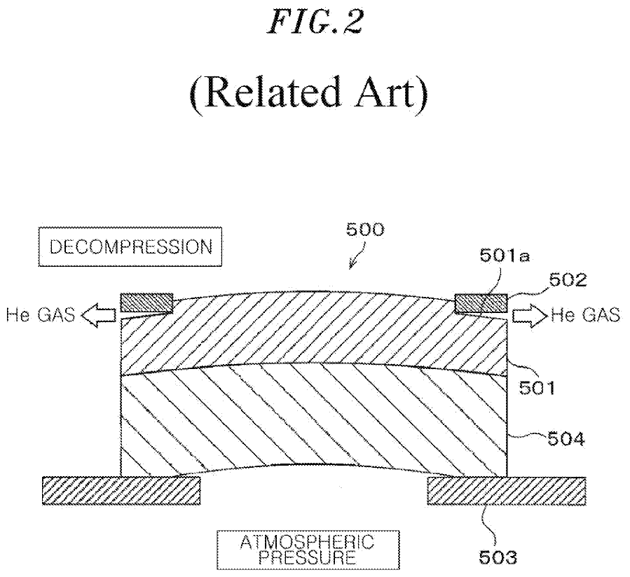

Meanwhile, as shown in FIG. 1, a ring supporting surface 501a of an electrostatic chuck 501 of a substrate support 500 and a lower surface of an edge ring 502 are respectively, for example, formed of substantially horizontal flat surfaces. When the inside of the chamber 503 is at atmospheric pressure, the ring supporting surface 501a of the electrostatic chuck 501 is a substantially horizontal flat surface; however, when the inside of the chamber 503 is decompressed, for example, during plasma processing, as shown in FIG. 2, the ring supporting surface 501a is deformed from a substantially horizontal flat surface. The reason is as follows.

Specifically, the substrate support 500 has a lower surface the periphery of which is fixed to the chamber 503. Further, due to the structure of the chamber 503, even when the inside of the chamber 503 is decompressed and the surroundings of the upper portion of the substrate support 500 (e.g., an upper surface of the base 504 and the electrostatic chuck 501) is decompressed, a central portion of the lower surface of the substrate support 500 still remains at atmospheric pressure. Therefore, when the inside of the chamber 503 is decompressed, the base 504 and the electrostatic chuck 501 are deformed such that central portions thereof protrude upward, and the ring supporting surface 501a is also deformed from the substantially horizontal flat surface.

In a case where deformation takes place as described above, even if the edge ring 502 is electrostatically attracted, the edge ring 502 is not deformed in the same way as does the ring supporting surface 501a. As a result, a gap with a height of 5 μm to 20 μm is formed between the ring supporting surface 501a and the lower surface of the edge ring 502. In this case, a heat transfer gas such as helium (He) gas leaks from the gap.

The technique according to the present disclosure restrains the leakage of the heat transfer gas. Hereinafter, the substrate support, the substrate processing apparatus, and the electrostatic attraction method according to this embodiment will be described with reference to the drawings. In addition, in this specification and drawings, the same reference numerals will be assigned to the same elements having the same configuration or function and a redundant detailed description thereof will be omitted.

<Plasma Processing System>

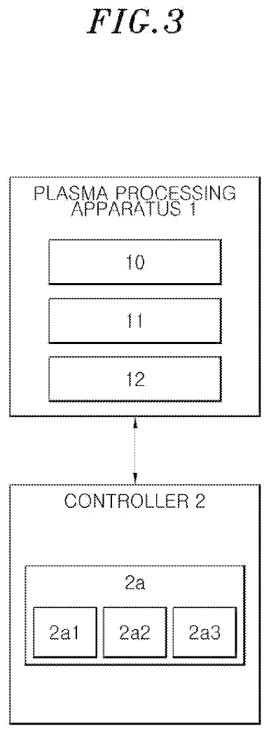

First, a plasma processing system according to an embodiment will be described with reference to FIG. 3. FIG. 3 is an explanatory diagram schematically showing the configuration of a plasma processing system.

In one embodiment, the plasma processing system includes a plasma processing apparatus 1, which is an example of a substrate processing apparatus, and a controller 2. The plasma processing apparatus 1 includes a plasma processing chamber 10, a substrate support 11, and a plasma generator 12. The plasma processing chamber 10 has a plasma processing space. In addition, the plasma processing chamber 10 has at least one gas inlet for supplying at least one processing gas to the plasma processing space and at least one gas outlet for discharging the gas from the plasma processing space. The gas inlet is connected to a gas supply 20 to be described later, and the gas outlet is connected to an exhaust system 40 to be described later. The substrate support 11 is disposed in the plasma processing chamber 10 and has a substrate supporting surface to support a substrate.

The plasma generator 12 is configured to generate plasma from at least one processing gas supplied into the plasma processing space. The plasma generated in the plasma processing space may be capacitively coupled plasma (CCP), an inductively coupled plasma (ICP), an electron cyclotron resonance (ECR) plasma, a Helicon excitation plasma (HWP), a surface wave plasma (SWP), etc. In addition, various types of plasma generators may be used, including an alternating current (AC) plasma generator and a direct current (DC) plasma generator. In one embodiment, an AC signal (AC power) used in the AC plasma generator has a frequency in the range of 100 kHz to 10 GHz. Therefore, the AC signal includes a radio frequency (RF) signal and a microwave signal. In one embodiment, the RF signal has a frequency in the range of 200 kHz to 150 MHz.

The controller 2 processes computer-executable instructions that cause the plasma processing apparatus 1 to perform various processes described in the present disclosure. The controller 2 may be configured to control each element of the plasma processing apparatus 1 to perform various processes described herein. In one embodiment, the entire or a part of the controller 2 may be included in the plasma processing apparatus 1. The controller 2 may include, for example, a computer 2a. The computer 2a may include, for example, a processor (for example, a Central Processing Unit (CPU)) 2a1, a memory 2a2, and a communication interface 2a3. The processor 2a1 may be configured to execute various control operations based on a program stored in the memory 2a2. The memory 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

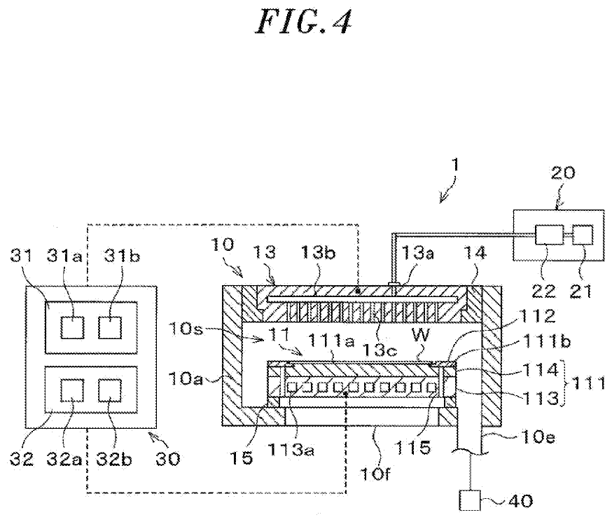

Hereinafter, a configuration of a capacitively coupled plasma (CCP) processing apparatus will be described as an example of the plasma processing apparatus 1 with reference to FIG. 4. FIG. 4 is a longitudinal sectional diagram schematically showing a configuration of the plasma processing apparatus 1. Although the plasma processing apparatus 1 of this embodiment performs plasma processing on a substrate (wafer) W, the substrate W to be plasma-processed is not limited to a wafer.

The CCP processing apparatus 1 includes a plasma processing chamber 10, a gas supply 20, a power source 30, and an exhaust system 40. In addition, the plasma processing apparatus 1 includes the substrate support 11 and a gas introduction portion. The gas introduction portion is configured to introduce at least one processing gas into the plasma processing chamber 10. The gas inlet includes a shower head 13. The substrate support 11 is disposed in the plasma processing chamber 10. The shower head 13 is disposed above the substrate support 11. In one embodiment, the shower head 13 forms at least a portion of a ceiling of the plasma processing chamber 10. The plasma processing chamber 10 has a plasma processing space 10s defined by the shower head 13, a sidewall 10a of the plasma processing chamber 10, and the substrate support 11. The sidewall 10a is grounded. The shower head 13 and the substrate support 11 are electrically insulated from the plasma processing chamber 10 housing.

The substrate support 11 includes a main body 111 and an edge ring 112. The main body 111 has a central region (substrate supporting surface) 111a for supporting the substrate (wafer) W, and an annular region (ring supporting surface) 111b for supporting the edge ring 112. As seen in a plan view, the annular region 111b of the main body 111 surrounds the central region 111a of the main body 111. The substrate W is disposed on the central region 111a of the body part 111, and the edge ring 112 is disposed on the annular region 111b to surround the substrate W on the central region 111a of the body part 111.

In one embodiment, the main body 111 may include a base 113 and an electrostatic chuck 114. The base 113 includes a conductive member. The conductive member of the base 113 functions as a lower electrode. The electrostatic chuck 114 is disposed on the base 113. An upper surface of the electrostatic chuck 114 has the substrate supporting surface 111a. In one embodiment, the upper surface of the electrostatic chuck 114 also has the ring supporting surface 111b.

The edge ring 112 is disposed to surround the substrate W on the substrate supporting surface 111a.

Further, the substrate support 11 may include a temperature control module configured to control at least one of the electrostatic chuck 114, the edge ring 112, and the substrate W to a target temperature. The temperature control module may include a heater, a heat transfer medium, a flow path 113a, or a combination thereof. A heat transfer fluid such as brine or gas flows through the flow path 113a. In one embodiment, the flow path 113a is formed in the base 113.

Further, the substrate support 11 includes a heat transfer gas supply path 115 to supply a heat transfer gas between a lower surface of the edge ring 112 and the ring supporting surface 111b. Further, the substrate support 11 may include a heat transfer gas supply path to supply a heat transfer gas between a rear surface of the substrate W and the substrate supporting surface 111a. A heat transfer gas from a heat transfer gas supply (not shown) is supplied to each heat transfer gas supply path.

The above-described heat transfer gas supply may include at least one gas source and at least one flow rate controller. In one embodiment, the heat transfer gas supply is configured to supply at least one heat transfer gas from the corresponding gas source to each heat transfer gas supply path through a flow rate controller corresponding to a corresponding heat transfer gas supply path. Each flow rate controller may include, for example, a mass flow rate controller or a pressure-controlled flow rate controller. Further, the heat transfer gas supply may include at least one flow rate modulating device that modulates or pulses the flow rate of the at least one heat transfer gas.

The shower head 13 is configured to introduce at least one processing gas from the gas supply 20 into the plasma processing space 10s. The shower head 13 has at least one gas inlet 13a, at least one gas diffusion chamber 13b, and a plurality of gas introduction ports 13c. The processing gas supplied to the gas inlet 13a passes through the gas diffusion chamber 13b and is introduced into the plasma processing space 10s from the plurality of gas introduction ports 13c. Also, the shower head 13 includes a conductive member. The conductive member of the shower head 13 functions as an upper electrode. Further, in addition to the shower head 13, the gas introduction portion may include one or a plurality of side gas injectors (SGIs) mounted in one or a plurality of openings formed in the side wall 10a.

The gas supply 20 may include at least one gas source 21 and at least one flow rate controller 22. In one embodiment, the gas supply 20 is configured to supply at least one process gas from a corresponding gas source 21 to the shower head 13 via a respective flow rate controller 22. Each flow rate controller 22 may include, for example, a mass flow rate controller or a hydraulic flow rate controller. Further, the gas supply 20 may include at least one flow rate modulation device for modulating or pulsing a flow rate of the at least one processing gas.

The power source 30 includes an RF power source 31 coupled to the plasma processing chamber 10 through at least one impedance matching circuit. The RF power source 31 is configured to supply at least one RF signal (RF power), such as a source RF signal and a bias RF signal, to a conductive member of the substrate support 11 and/or a conductive member of the shower head 13. Accordingly, plasma is generated from at least one processing gas supplied to the plasma processing space 10s. Therefore, the RF power source 31 may function as at least a part of the plasma generator 12. In addition, by supplying a bias RF signal to the conductive member of the substrate support 11, it is possible to generate a bias potential in the substrate W and introduce ion components in the formed plasma into the substrate W.

In one embodiment, the RF power source 31 includes a first RF generator 31a and a second RF generator 31b. The first RF generator 31a is coupled to the conductive member of the substrate support 11 and/or the conductive member of the shower head 13 through at least one impedance matching circuit, and is configured to generate a plasma source RF signal (source RF power). In one embodiment, the source RF signal has a frequency in the range of 13 MHz to 150 MHz. In one embodiment, the first RF generator 31a may be configured to generate a plurality of source RF signals having different frequencies. The generated one or more source RF signals are supplied to the conductive member of the substrate support 11 and/or the conductive member of the shower head 13. The second RF generator 31b is coupled to the conductive member of the substrate support 11 through at least one impedance matching circuit, and is configured to generate a bias RF signal (bias RF power). In one embodiment, the bias RF signal has a lower frequency than that of a source RF signal. In one embodiment, the bias RF signal has a frequency in the range of 400 kHz to 13.56 MHz. In one embodiment, the second RF generator 31b may be configured to generate a plurality of bias RF signals having different frequencies. The generated one or more bias RF signals are supplied to the conductive member of the substrate support 11. Further, in various embodiments, at least one of the source RF signal and the bias RF signal may be pulsed.

The power source 30 may also include a DC power source 32 coupled to the plasma processing chamber 10. The DC power source 32 includes a first DC generator 32a and a second DC generator 32b. In one embodiment, the first DC generator 32a is connected to the conductive member of the substrate support 11 and is configured to generate a first DC signal. The generated first DC signal is applied to a conductive member of the substrate support 11. In one embodiment, the first DC signal may be applied to a different electrode, such as an electrode in the electrostatic chuck 114. In one embodiment, the second DC generator 32b is connected to the conductive member of the shower head 13 and is configured to generate a second DC signal. The generated second DC signal is applied to a conductive member of the shower head 13. In various embodiments, the first and second DC signals may be pulsed. In addition, the first and second DC generators 32a and 32b may be provided in addition to the RF power source 31, and the first DC generator 32a may be provided instead of the second RF generator 31b.

The exhaust system 40 may be connected to, for example, a gas outlet 10e provided at a bottom of the plasma processing chamber 10. The exhaust system 40 may include a pressure regulating valve and a vacuum pump. Pressure in the plasma processing space 10s is regulated by the pressure regulating valve. The vacuum pump may include a turbo molecular pump, a dry pump, or a combination thereof.

<Substrate Support>

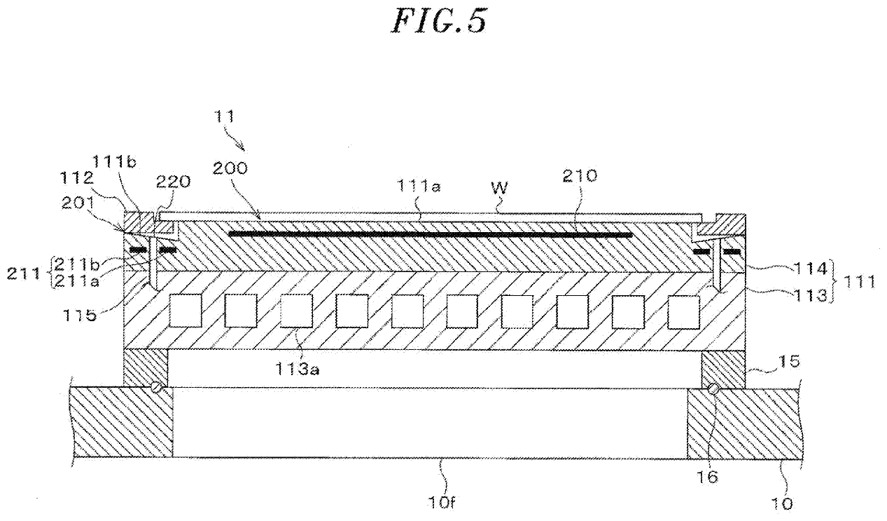

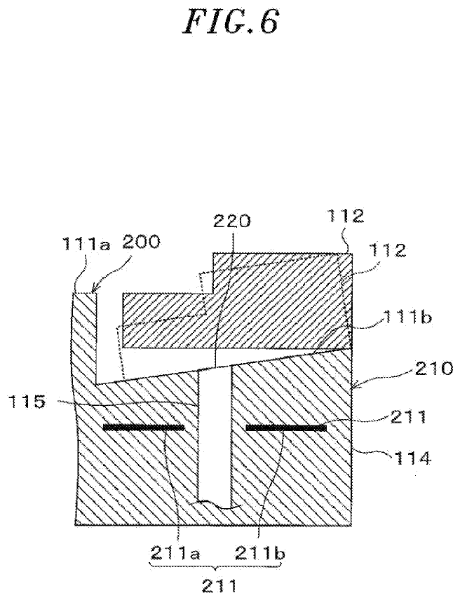

Next, with reference to FIG. 4, the configuration of the above-mentioned substrate support 11 will be further described using FIG. 5 and FIG. 6. FIG. 5 is a cross-sectional view showing a state of the substrate support 11 in the plasma processing chamber 10, which shows a state when the entire surroundings of the substrate support 11 are at atmospheric pressure. FIG. 6 is a partially enlarged cross-sectional view of FIG. 5. However, the wafer W is not illustrated in FIG. 6.

As shown in FIG. 4, the substrate support 11 is accommodated in the plasma processing chamber 10. Specifically, the substrate support 11 is accommodated in the plasma processing chamber 10 such that the lower surface of the substrate support 11 is exposed to an atmosphere at higher pressure than that of the inside of the decompressed pressure plasma processing chamber 10. More specifically, the substrate support 11 is accommodated in the plasma processing chamber 10 such that an opening 10f provided at the bottom of the plasma processing chamber 10 is blocked at the lower surface of the substrate support 11. For example, by fixing the lower surface of the periphery of the substrate support 11 at the bottom of the plasma processing chamber 10 through a cylindrical leg portion 15 provided so as to surround an outer circumference of the opening 10f, it is possible to block the opening 10f at the lower surface of the substrate support 11. Further, the leg portion 15 is formed by an insulator. In one embodiment, an O-ring 16 is provided as a sealing member between the bottom of the plasma processing chamber 10 and the leg 15, as shown in FIG. 5.

As described above, the substrate support 11 includes the main body 111 and the edge ring 112. In one embodiment, the main body 111 includes the base 113 and the electrostatic chuck 114.

Further, in one embodiment, the base 113 is made of a conductive material such as Aluminum (Al). The base 113 and the electrostatic chuck 114 are integrated with each other, for example, by bonding.

In the electrostatic chuck 114, a central portion 200 with a substrate supporting surface 111a and an outer peripheral portion 201 with a ring supporting surface 111b are integrally formed with each other. The central portion 200 and the outer peripheral portion 201 of the electrostatic chuck 114 may be provided separately. The central portion 200 protrudes from the outer peripheral portion 201, and the substrate supporting surface 111a of the central portion 200 is higher than the ring supporting surface 111b of the outer peripheral portion 201.

The edge ring 112 supported by the ring supporting surface 111b is a member disposed so as to surround the substrate W on the substrate supporting surface 111a. The edge ring 112 is formed in an annular shape. More specifically, as seen in a plan view, the edge ring 112 is in an annular shape. In one embodiment, the lower surface of the edge ring 112 is formed by a flat surface, whose cross-sectional height is constant from an inner portion to a periphery portion and which becomes substantially horizontal when supported by the substrate support surface 111a. For the material of the edge ring 112, for example, silicon carbide (SiC), silicon (Si), silicon dioxide (SiO₂), tungsten (W), tungsten carbide (WC), or ceramic is used.

The central portion 200 of the electrostatic chuck 114 is formed to have a smaller diameter than a diameter of the substrate W, for example. When the substrate W is mounted to the substrate supporting surface 111a, the peripheral portion of the substrate W protrudes from the central portion 200 of the electrostatic chuck 114.

In one embodiment, as shown in FIG. 6, the edge ring 112 has a step at an upper part thereof, and an upper surface of the outer peripheral portion is formed higher than an upper surface of an inner peripheral portion. The inner peripheral portion of the edge ring 112 may be formed so as to slide into a lower side of a periphery of the substrate W protruding from the central portion 200 of the electrostatic chuck 114. That is, an inner diameter of the edge ring 112 may be formed smaller than an outer diameter of the substrate W.

In addition, an electrode 210 for electrostatically attracting the substrate W is provided in the central portion 200 of the electrostatic chuck 114. An electrode 211 for electrostatically attracting the edge ring 112 is provided at the outer peripheral portion 201 of the electrostatic chuck 114. In one embodiment, the electrode 211 is a bipolar electrode including a pair of electrodes 211a and 211b. For example, a first electrode 211a and a second electrode 211b are formed in an annular shape in a plan view and are arranged concentrically with each other. In addition, the first electrode 211a is positioned at an inner side, and the second electrode 211b is positioned at an outer side. The first electrode 211a and the second electrode 211b may be divided in a circumferential direction.

A DC voltage is applied from a DC power source (not shown) to the electrode 210. By an electrostatic force generated accordingly, the substrate W is attracted and held by the substrate supporting surface 111a.

Similarly, a DC voltage is applied from a DC power source to the electrode 211. Specifically, a DC voltage is applied from the DC power source to the electrode 211 such that a potential difference occurs between the first electrode 211a and the second electrode 211b. By an electrostatic force generated accordingly, the edge ring 112 is attracted and held by the ring supporting surface 111b.

In addition, as described above, the substrate support 11 includes the heat transfer gas supply path 115 to supply a heat transfer gas between the lower surface of the edge ring 112 and the ring supporting surface 111b. In one embodiment, a heat transfer gas inlet 220 is formed in the ring supporting surface 111b of the outer peripheral portion 201 of the electrostatic chuck 114. The heat transfer gas supplied to the heat transfer gas supply path 115 is supplied from the heat transfer gas inlet 220 to a space between the lower surface of the edge ring 112 and the ring supporting surface 111b. The heat transfer gas inlet 220 is connected to a heat transfer gas supply (not shown). The heat transfer gas supply includes, for example, a gas source 21 for the heat transfer gas and a flow rate controller for controlling a supply of the heat transfer gas. The flow rate controller 22 includes, for example, a flow rate controller such as a mass flow rate controller or a valve.

In addition, in one embodiment, the heat transfer gas inlet 220 also serves as a suction port. By evacuating a space between the ring supporting surface 111b and the edge ring 112 through the heat transfer gas inlet 220 as a suction port, it is possible to vacuum suction the edge ring 112 to the ring supporting surface 111b. Further, the heat transfer gas inlet 220 as a suction port is connected to an exhaust system (not shown). The exhaust system includes, for example, an exhaust regulating valve and a vacuum pump. The suction port and the heat transfer gas inlet 220 may be provided separately.

In addition, the ring supporting surface 111b of the electrostatic chuck 114 is formed such that an inner edge side thereof is lower than an outer edge side thereof. Specifically, the ring supporting surface 111b of the electrostatic chuck 114 is formed so that an inner edge side thereof is lower than an outer edge side thereof in a state in which the plasma processing chamber 10 is not decompressed, that is, in a no-load state. For example, the ring supporting surface 111b of the electrostatic chuck 114 is an inclined surface of which an inner edge side is lower than an outer edge side. A width of the electrostatic chuck 114 in a radial direction is, for example, 15 mm, and a difference in height between an inner peripheral end and an outer peripheral end of the electrostatic chuck 114 is, for example, 8 μm. An angle of an inclined surface of the ring supporting surface 111b relative to a horizontal plane (in a no-load state) is, for example, 0.03° to 0.06°.

In addition, an inner diameter of the edge ring 112 supported by the ring supporting surface 111b is, for example, set as follows. That is, the inner diameter of the edge ring 112 is set such that a gap is formed between an inner peripheral surface (hereinafter, a ring inner peripheral surface) of the edge ring 112 and an outer peripheral surface of the central portion 200 of the electrostatic chuck 114. More specifically, the inner diameter of the edge ring 112 may be set such that an inner peripheral surface of a ring does not come into contact with an outer peripheral surface of the central portion 200 when the edge ring 112 is electrostatically attracted, as indicated by a dotted line in FIG. 6.

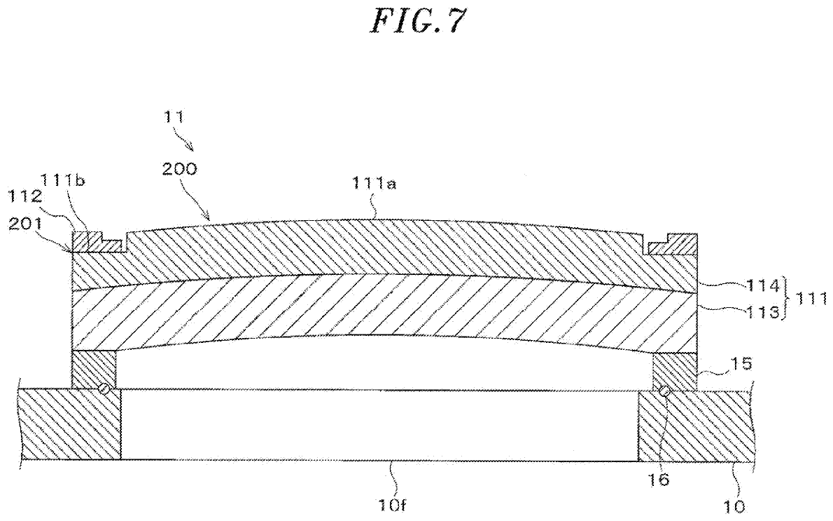

Next, the operation of the ring supporting surface 111b formed as described above will be described. FIG. 7 is a view showing a main part of the substrate support 11 when the plasma processing chamber 10 is decompressed, in which the flow path 113, the heat transfer gas supply path 115, the electrodes 210 and 211, and the like are omitted.

When pressure in the plasma processing chamber 10 is reduced, the surroundings of the upper part of the substrate support 11 (e.g., the upper surface of the base 113 and the electrostatic chuck 114, etc.) become under a decompressed atmosphere. However, even if the pressure of the plasma processing chamber 10 is reduced, the periphery of the central portion of the lower surface (specifically, the lower surface of the base 113) of the substrate support 11 remains at the same pressure as before a start of the decompression: in other words, the periphery remains at an atmospheric pressure. Therefore, the base 113 and the electrostatic chuck 114 are deformed so that central portions thereof protrude upward. In a case where deformation takes place in this way, if the ring supporting surface 111b is a substantially horizontal flat surface in a no-load state as described above with reference to FIGS. 1 and 2, which is unlike the present embodiment, a heat transfer gas leaks into the plasma processing space 10s from a gap between the ring supporting surface 111b and the lower surface of the ring 112.

In contrast, in the present embodiment, the ring supporting surface 111b is formed so that an inner edge side thereof is lower than an outer edge side thereof in a no-load state. Thus, as shown in FIG. 7, when the base 113 and the electrostatic chuck 114 are deformed so that central portions thereof protrude upward, and accordingly, when the outer peripheral portion 201 of the electrostatic chuck 114 is also deformed, the ring supporting surface 111b becomes substantially horizontal. Therefore, compared to the case where the ring supporting surface 111b is a substantially horizontal flat surface in the no-load state, it is possible to reduce the gap between the ring supporting surface 111b and the lower surface of the edge ring 112 when the pressure of the plasma processing chamber 10 is reduced. Accordingly, it is possible to restrain a leakage of the heat transfer gas from the gap.

In addition, in a case where the gap is small, at a time of electrostatic attraction of the edge ring 112 to the ring supporting surface 111b, the edge ring 112 may be deformed, such that the lower surface of the edge ring 112 and the ring supporting surface 111b are brought into close contact with each other substantially entirely. Therefore, it is possible to further restrain a leakage of the heat transfer gas from the gap.

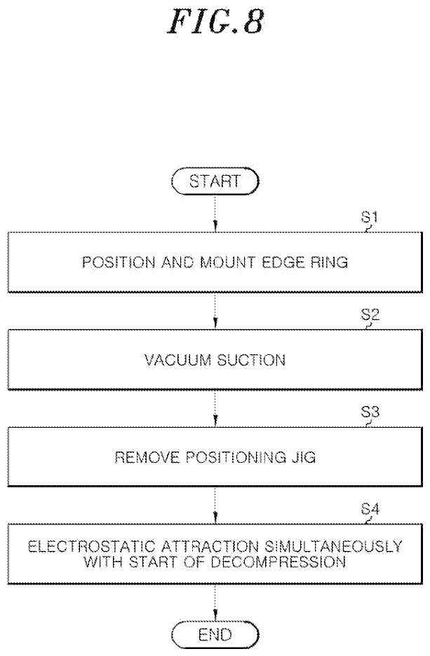

Next, an electrostatic attraction method of the edge ring 112 will be described with reference to FIGS. 8 and 9. FIG. 8 is a flowchart for explaining an example of an electrostatic attraction method of the edge ring 112. FIG. 9 is a diagram illustrating a state of the electrostatic chuck 114 in a process of mounting an edge ring.

First, for example, as shown in FIG. 8, the edge ring 112 is positioned, by an operator, on the ring supporting surface 111b of the electrostatic chuck 114 with respect to the substrate supporting surface 111a and is mounted thereto (Step S1). Positioning of the edge ring 112 with respect to the substrate supporting surface 111a is performed using a positioning jig J, as shown in FIG. 9. In one embodiment, the positioning jig J is used by being inserted between the outer peripheral surface of the central portion 200 of the electrostatic chuck 114 and the inner peripheral surface of the edge ring 112. By using the positioning jig J, for example, it is possible to keep a constant distance between the outer peripheral surface of the central portion 200 of the electrostatic chuck 114 and the inner peripheral surface of the edge ring 112 in a circumferential direction of the electrostatic chuck 114.

Then, the edge ring 112 supported by the ring supporting surface 111b is vacuum-suctioned (Step S2). Specifically, through the heat transfer gas inlet 220 as a suction port, air between the ring supporting surface 111b and the lower surface of the edge ring 112 is exhausted, thereby causing the edge ring 112 vacuum-suctioned to the ring supporting surface 111b.

Then, the positioning jig J is removed from the electrostatic chuck 114 by the operator (Step S3).

Subsequently, at the same time as decompression of the plasma processing chamber 10 starts, the edge ring 112 supported by the ring supporting surface 111b is electrostatically attracted (Step S4). Specifically, at the same time as decompression of the plasma processing chamber 10 starts, a DC voltage is applied to the electrode 211 and the edge ring 112 is electrostatically attracted to the ring supporting surface 111b by an electrostatic force generated accordingly. As described above, a process of electrostatic attraction of the series of edge rings 112 is completed.

After the edge ring 112 is attracted, a heat transfer gas is supplied between the ring supporting surface 111b and the edge ring 112 at a desired timing (e.g., at the start of plasma processing, etc.).

As described above, in the present embodiment, the ring supporting surface 111b of the substrate support 11 is formed such that the inner edge side thereof is lower than the outer side thereof in a no-load state. Therefore, according to the present embodiment, when the plasma processing chamber 10 is decompressed, the gap between the lower surface of the edge ring 112 and the ring supporting surface 111b may be reduced, possibly restraining a leakage of the heat transfer gas from the gap. As a result, it is also possible to restrain a trouble caused by the leakage of heat transfer gas.

Further, in a method of reducing the gap between the lower surface of the edge ring 112 and the ring supporting surface 111b when the plasma processing chamber 10 is decompressed, the following method of restraining deformation of a substrate support may be considered, which is different from the above-described embodiment. That is, it is a method of increasing rigidity by changing a thickness or material of the electrostatic chuck 114 and of reducing the gap by restraining deformation of the substrate support 11. In addition, a method of reducing the gap by securing the central portion of the lower surface of the substrate support 11 to the plasma processing chamber 10 and restraining deformation of the substrate support 11 occurring at a time of decompression of the plasma processing chamber 10 may also be considered. However, the structure of the substrate support 11 is designed in consideration of characteristics of a substrate attracting region (attracting characteristics, heat generating characteristics, etc.). Therefore, it is not preferable to provide restrictions on the structure of the substrate support 11 in order to restrain deformation of the substrate support 11, because the degree of freedom in design is decreased. In this regard, in the present embodiment, since the gap can be made small only by slightly changing the shape of the ring supporting surface 111b from a conventional one, the degree of freedom in design is not deteriorated.

In the present embodiment, the ring supporting surface 111b is an inclined surface. However, the shape of the ring supporting surface 111b is not limited thereto, and it is preferable that the inner edge side of the ring supporting surface 111b is lower than the outer edge side thereof in a no-load state. Specifically, it is preferable that an angle of a surface connecting the inner and outer edges relative to a horizontal plane is 0.03° to 0.06° in a no-load state.

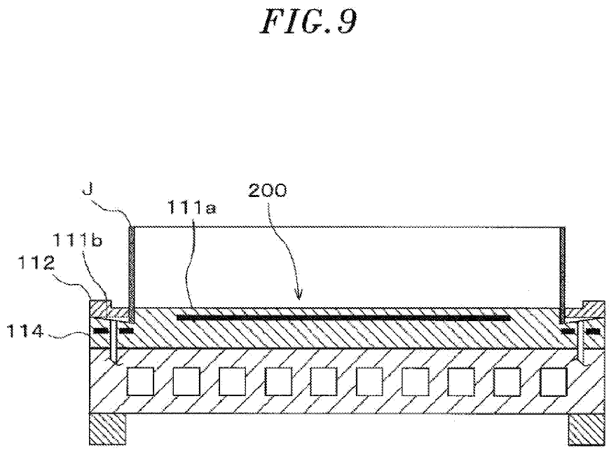

For example, like a ring supporting surface 300 shown in FIG. 10, the ring supporting surface 111b may be formed with a stepped structure having steps that increase in height from the inner edge side to the outer edge side in a no-load state.

Further, like a ring supporting surface 310 shown in FIG. 11, the ring supporting surface 111b may be formed with a step between the inner and outer edge sides such that the inner edge side is lower than the outer edge side in a no-load state.

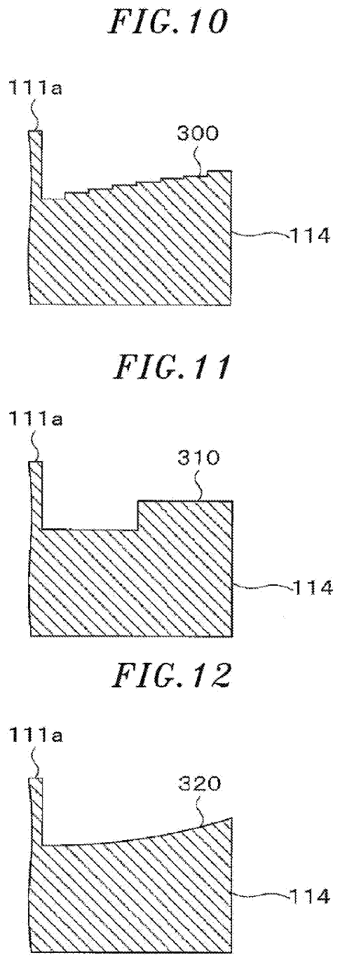

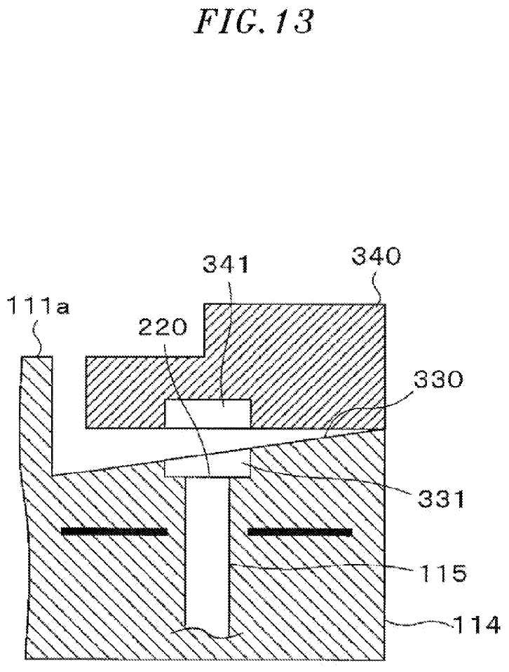

Further, like a ring supporting surface 320 shown in FIG. 12, the ring supporting surface 111b may be a curved surface which increases in height from an inner edge side to an outer edge side in a no-load state.

Even if any of the ring supporting surfaces 300, 310, and 320 is given, it is possible to reduce the gap between the lower surface of the edge ring 112 and a corresponding ring supporting surface when the plasma processing chamber 10 is decompressed, compared to the ring supporting surface 111b that is a substantially horizontal flat surface in a no-load state. In addition, it is possible to restrain a leakage of heat transfer gas from the gap.

Further, in the ring supporting surface 330, a groove 331 communicating with the heat transfer gas inlet 220 may be formed, as shown in FIG. 13. The groove 331 is formed to extend in the circumferential direction of the electrostatic chuck 114, for example. In one embodiment, the groove 331 is formed in an annular shape concentric with the electrostatic chuck 114, as seen in a plan view.

In addition, a groove 341 recessed upwardly may be formed in the lower surface of the edge ring 340 at a position corresponding to the heat transfer gas inlet 220. In one embodiment, the position of the groove 341 is a position facing the heat transfer gas inlet 220 when the plasma processing chamber 10 is decompressed and the electrostatic chuck 114 is deformed. The groove 341 is formed to extend in the circumferential direction of the edge ring 340, for example. In one embodiment, the groove 341 is formed in an annular shape concentric with the edge ring 340, as seen in a plan view.

By at least either one of the formation of the groove 331 in the ring supporting surface 330 or the formation of the groove 341 in the lower surface of the edge ring 340, the heat transfer gas may be transferred in the circumferential direction. Therefore, it is possible to further restrain a leakage of the heat transfer gas. Further, it is possible to improve temperature control in the edge ring 112, thereby improving uniformity of temperature distribution in the edge ring 112.

Although a voltage applied to the electrode 211 is, for example, constant, the voltage may be changed based on a temperature of a temperature control fluid flowing through the flow path 113a, as will be described below. The change of the voltage applied to the electrode 211 based on the temperature of the temperature control fluid is executed by the controller 2.

When the lower surface of the edge ring 112 is horizontal while being supported by the ring supporting surface 111b, it is preferable that the ring supporting surface 111b is also horizontal when the plasma processing chamber 10 is decompressed and the base 113 and the electrostatic chuck 114 are deformed. Accordingly, in one embodiment, the ring supporting surface 111b is designed so as to be horizontal when the plasma processing chamber 10 is decompressed and the base 113 and the electrostatic chuck 114 are deformed. Meanwhile, the electrostatic chuck 114 and the base 113 have different coefficients of thermal expansion due to, for example, different materials, and the base 113 has a large coefficient of thermal expansion.

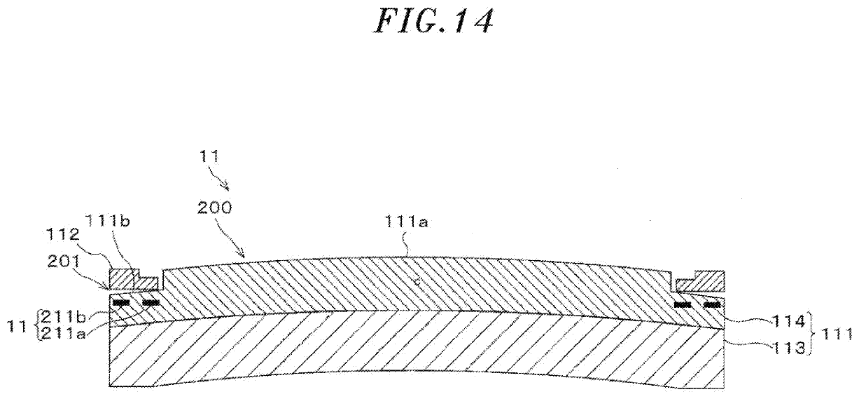

Therefore, when the temperature control fluid flowing through the flow path 113a is high, the base 113 becomes thermally expanded, thereby resulting in the electrostatic chuck 114 being pulled outward by the base 113. As a result, as shown in FIG. 14, when the plasma processing chamber 10 is decompressed and the base 113 and the electrostatic chuck 114 are deformed, the ring supporting surface 111b does not become horizontal as designed, but may be inclined to be lower toward the outer edge side. In this way, when the ring supporting surface 111b become inclined, a gap may be formed between the lower surface of the edge ring 112 and the outer edge side of the ring supporting surface 111b. Therefore, when the temperature control fluid flowing through the flow path 113a is at a high temperature, it is preferable to increase a magnitude of a voltage applied to the second electrode 211 in the outer side than that of a voltage applied to the first electrode 211a in an inner side in order to reduce the aforementioned gap, such that the outer edge side of the edge ring 112 is more strongly electrostatically attracted by the electrode 211.

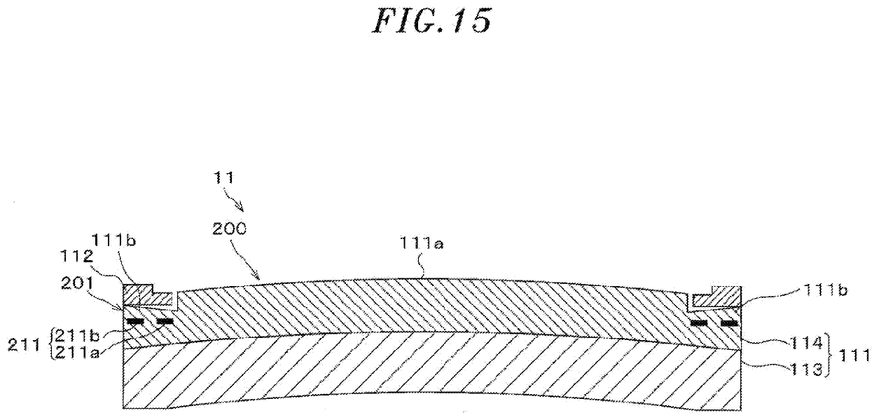

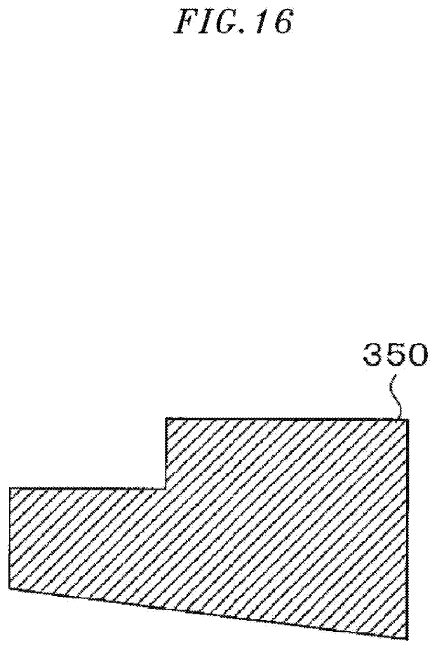

In addition, when the temperature control fluid flowing through the flow path 113a is at a low temperature, the base 113 becomes thermally contracted, thereby resulting in the electrostatic chuck 114 being pulled inward by the base 113. As a result, as shown in FIG. 15, when the plasma processing chamber 10 is decompressed and the base 113 and the electrostatic chuck 114 are deformed, the ring supporting surface 111b does not become horizontal as designed, but may be inclined to be lowered toward the inner edge side. In this way, when the ring supporting surface 111b become inclined, a gap may be formed between the lower surface of the edge ring 112 and the inner edge side of the ring supporting surface 111b. Therefore, when the temperature control fluid flowing through the flow path 113a is at a low temperature, it is preferable to increase a magnitude of a voltage applied to the first electrode 211a in the inner side than that of a voltage applied to the second electrode 211b in the outer side in order to reduce the aforementioned gap, so that the inner edge side of the edge ring 112 is more strongly electrostatically attracted by the electrode 211.

In the above description, the lower surface of the edge ring 112 is at a constant height from the inner edge side to the outer edge side in a cross-sectional view, and the lower surface of the edge ring 112 is horizontal while being supported by the ring supporting surface 111b. However, as shown in FIG. 16, the lower surface of the edge ring 350 may be formed such that the inner edge side thereof is higher than the outer edge side in a cross-sectional view. If the edge ring 112 is in this shape, it is possible to bring the lower surface of the edge ring 350 and the ring supporting surface 111b into close contact with each other substantially entirely even in a case where the ring supporting surface 111b is inclined so as to be lower toward the outer edge side when the plasma processing chamber 10 is decompressed, as shown in FIG. 14.

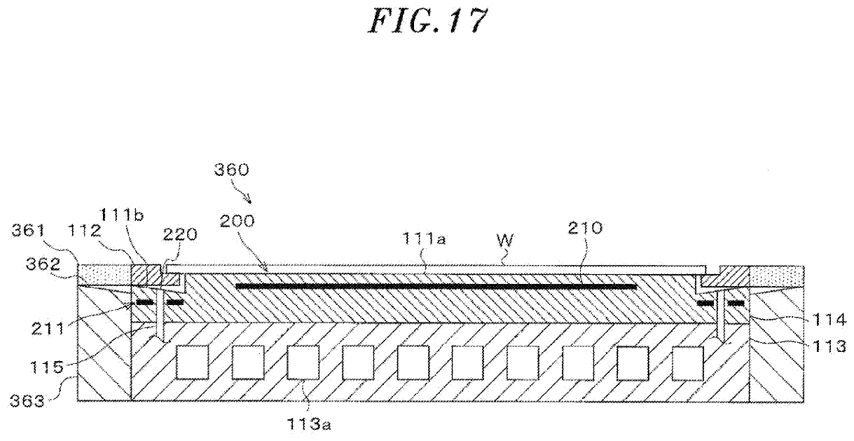

As shown in FIG. 17, the substrate support 360 may have a cover ring 361 and another ring supporting surface 362. The cover ring 361 is a member disposed to cover the outer surface of the edge ring 112, and the ring supporting surface 362 is formed to surround the outer side of the ring supporting surface 111b and to support the cover ring 361. In a case where the substrate support 360 further has an element for supplying a heat transfer gas between the lower surface of the cover ring 361 and the ring supporting surface 362, the ring supporting surface 362 may be formed to have an inner edge side lower than an outer edge side thereof, similarly to the ring supporting surface 111b. Accordingly, it is possible to restrain a leakage of the heat transfer gas from the gap between the lower surface of the cover ring 361 and the ring supporting surface 362.

In one embodiment, the ring supporting surface 362 is provided in an annular insulating member 363 that surrounds outer circumferences of the electrostatic chuck 114 and the base 113.

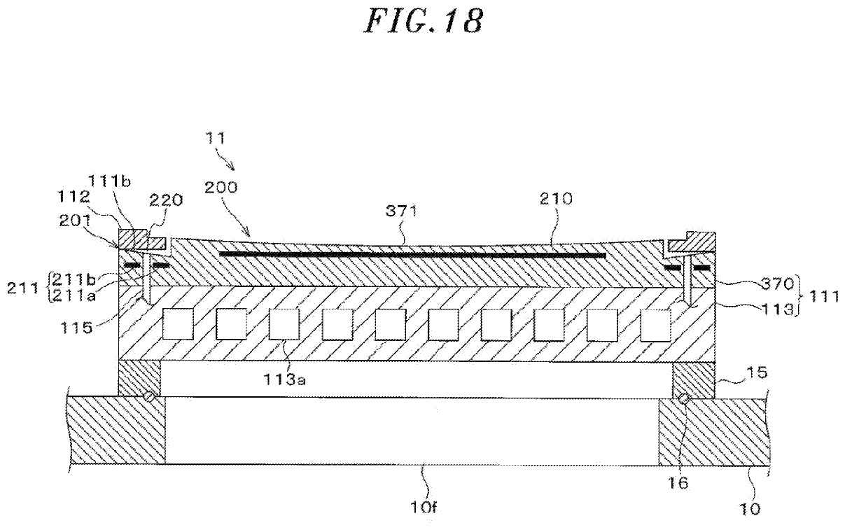

Also, as shown in FIG. 18, the substrate supporting surface 371 of the electrostatic chuck 370 may be concave downward in a cross-sectional view in a state in which the plasma processing chamber 10 is not decompressed. Accordingly, when the plasma processing chamber 10 is decompressed and the electrostatic chuck 370 is deformed so that the central portions thereof protrude upward, the substrate supporting surface 371 becomes substantially horizontal. Therefore, compared to the case where the substrate supporting surface 371 of the electrostatic chuck 370 is formed so as to be horizontal when the plasma processing chamber 10 is not decompressed, the gap between the lower surface of the substrate W and the substrate supporting surface 371 become small. Accordingly, it is possible to restrain a leakage of heat transfer gas, which is supplied between the lower surface of the substrate W and the substrate supporting surface 371, from the gap.

It should be considered that the embodiments disclosed herein are illustrative in all respects and not restrictive. While the present disclosure has been shown and described with reference to exemplary embodiments thereof, it will be apparent to those of ordinary skill in the art that various changes in form and detail may be made thereto without departing from the spirit and scope of the present disclosure as defined by the following claims. The accompanying claims and their equivalents are intended to cover such forms or modifications as would fall within the scope and spirit of the disclosures.

1. A substrate support, comprising:
a base;
an electrostatic chuck disposed on the base and having a substrate supporting surface to support the substrate; and
an edge ring disposed to surround the substrate on the substrate supporting surface,
wherein the electrostatic chuck has a ring supporting surface to support the edge ring, and
an inner edge side of the ring supporting surface is lower than an outer edge side of the ring supporting surface.

2. The substrate support of claim 1, wherein the ring supporting surface has a heat transfer gas inlet for supplying a heat transfer gas between the ring supporting surface and the edge ring.

3. The substrate support of claim 2, wherein at least one of a lower surface of the edge ring and the ring supporting surface has a groove.

4. The substrate support of claim 1, wherein the ring supporting surface is an inclined surface.

5. The substrate support of claim 4, wherein an angle of the inclined surface is 0.03° to 0.06°.

6. The substrate support of claim 1, wherein the ring supporting surface is a curved surface that rises from the inner edge side toward the outer edge side.

7. The substrate support of claim 1, wherein the ring supporting surface has a step between the inner edge side and the outer edge side, or has a stepped shape that increases in height from the inner edge side toward the outer edge side.

8. The substrate support of claim 1, wherein the ring supporting surface has a first electrode and a second electrode, respectively provided in an inner side and an outer side of the ring supporting surface, for electrostatic attraction of the edge ring.

9. The substrate support of claim 8, wherein voltages are applied to the first electrode and the second electrode such that a potential difference between the first electrode and the second electrode occurs.

10. The substrate support claim 9, further comprising:
a flow path through which a temperature control fluid for controlling a temperature of the substrate flows,
wherein a magnitude of voltages applied to the first electrode and the second electrode is changed based on a temperature of the temperature control fluid flowing through the flow path.

11. The substrate support of claim 1, wherein the edge ring is made of silicon carbide (SiC), silicon (Si), silicon dioxide (SiO₂), tungsten (W), tungsten carbide (WC), or ceramic.

12. A substrate processing apparatus comprising:
a substrate support comprising:
a base;
an electrostatic chuck disposed on the base and having a substrate supporting surface to support the substrate; and
an edge ring disposed to surround the substrate on the substrate supporting surface,
wherein the electrostatic chuck has a ring supporting surface to support the edge ring, and
an inner edge side of the ring supporting surface is lower than an outer edge side of the ring supporting surface; and
a processing chamber configured to be decompressed and to accommodate the substrate support.

13. The substrate processing apparatus of claim 12, wherein the substrate support is accommodated in the processing chamber such that a central portion of a lower surface of the substrate support is exposed to an atmosphere of a higher pressure than a pressure of a decompressed internal space of the processing chamber.

14. A method for electrostatically attracting an edge ring to an electrostatic chuck of a substrate support of a substrate processing apparatus,
wherein the substrate processing apparatus is configured to be decompressed and comprises a processing chamber accommodating the substrate support,
wherein the substrate support comprises:
a base;
an electrostatic chuck disposed on the base and having a substrate supporting surface to support a substrate; and
the edge ring disposed to surround the substrate on the substrate supporting surface,
wherein the electrostatic chuck has a ring supporting surface to support the edge ring, and
an inner edge side of the ring supporting surface is lower than an outer edge side of the ring supporting surface,
wherein the method comprises:
electrostatically attracting the edge ring supported by the ring supporting surface of the substrate support; and
decompressing the processing chamber and deforming the base and the electrostatic chuck to bring an inner edge side of the ring supporting surface closer to a lower surface of the edge ring.
